(19) United States
(12) Patent Application Publication
(10) Pub. No.: US 2014/0158973 A1
(43) Pub. Date: Jun. 12, 2014

(54) NITRIDE-BASED MEMRISTORS

(71) Applicants: Jianhua Yang, Palo Alto, CA (US); Gilberto Medeiros Ribeiro, Palo Alto, CA (US); R. Stanley Williams, Portola Valley, CA (US)

(72) Inventors: Jianhua Yang, Palo Alto, CA (US); Gilberto Medeiros Ribeiro, Palo Alto, CA (US); R. Stanley Williams, Portola Valley, CA (US)

(21) Appl. No.: 14/236,822

(22) PCT Filed: Aug. 3, 2011
(86) PCT No.: PCT/US2011/046467

§ 371 Date: Feb. 3, 2014

(51) Int. Cl. H01L 45/00

(52) U.S. Cl. CPC H01L 45/145; H01L 45/1608
USPC 257/4; 438/382

(57) ABSTRACT

A nitride-based memristor memristor includes: a first electrode comprising a first nitride material; a second electrode comprising a second nitride material; and active region positioned between the first electrode and the second electrode. The active region includes an electrically semiconducting or nominally insulating and weak ionic switching nitride phase. A method for fabricating the nitride-based memristor is also provided.

### STATEMENT OF GOVERNMENT INTEREST

This invention has been made with government support. The government has certain rights in the invention.

### BACKGROUND

The continuous trend in the development of electronic devices has been to minimize the sizes of the devices. While the current generation of commercial microelectronics are based on sub-micron design rules, significant research and development efforts are directed towards exploring devices on the nano-scale, with the dimensions of the devices often measured in nanometers or tens of nanometers. In addition to the significant reduction of individual device size and much higher packing density as compared to microscale devices, nanoscale devices may also provide new functionalities due to physical phenomena on the nanoscale that are not observed on the micron scale.

For instance, electronic switching in nanoscale devices using titanium oxide as the switching material has recently been reported. The resistive switching behavior of such a device has been linked to the memristor circuit element theory originally predicted in 1971 by L. O. Chua. The discovery of the memristive behavior in the nanoscale switch has generated significant interest, and there are substantial on-going research efforts to further develop such nanoscale switches and to implement them in various applications. One of the many important potential applications is to use such a switching device as a memory unit to store digital data.

In order to be competitive with CMOS FLASH memories, the emerging resistive switches need to have a switching endurance that exceeds at least millions of switching cycles. Reliable switching channels inside the device may significantly improve the endurance of these switches. Different switching material systems are being explored to achieve memristors with desired electrical performance, such as high speed, high endurance, long retention, low energy and low cost.

### BRIEF DESCRIPTION OF THE DRAWINGS

FIG. 1 is an example of a present memristor device.

FIG. 2 is an example of a memristor device based on the principles disclosed herein.

FIG. 3 is a ternary phase diagram of the Al—Ti—N system, together with the binary phase diagrams of the Al—N and Ti—N systems, useful in the practice of the various examples disclosed herein.

FIG. 4 is a flow chart depicting an example method for fabricating a memristor in accordance with the examples disclosed herein.

FIG. 5 illustrates another example of a memristor device based on the principles disclosed herein.

### DETAILED DESCRIPTION

Reference is now made in detail to specific examples of the disclosed fully nitride memristor and specific examples of ways for creating the disclosed fully nitride memristor. When applicable, alternative examples are also briefly described.

As used in the specification and claims herein, the singular forms “a,” “an,” and “the” include plural referents unless the context clearly dictates otherwise.

As used in this specification and the appended claims, “approximately” and “about” mean a ±10% variance caused by, for example, variations in manufacturing processes.

In the following detailed description, reference is made to the drawings accompanying this disclosure, which illustrate specific examples in which this disclosure may be practiced. The components of the examples can be positioned in a number of different orientations and any directional terminology used in relation to the orientation of the components is used for purposes of illustration and is in no way limiting. Directional terminology includes words such as “top,” “bottom,” “front,” “back,” “leading,” “trailing,” etc.

It is to be understood that other examples in which this disclosure may be practiced exist, and structural or logical changes may be made without departing from the scope of the present disclosure. Therefore, the following detailed description is not to be taken in a limiting sense. Instead, the scope of the present disclosure is defined by the appended claims.

Memristors are nano-scale devices that may be used as a component in a wide range of electronic circuits, such as memories, switches, and logic circuits and systems. In a memory structure, a crossbar of memristors may be used. When used as a basis for memories, the memristor may be used to store a bit of information, 1 or 0. When used as a logic circuit, the memristor may be employed as configuration bits and switches in a logic circuit that resembles a Field Programmable Gate Array, or may be the basis for a wired-logic Programmable Logic Array.

When used as a switch, the memristor may either be a closed or open switch in a cross-point memory. During the last few years, researchers have made great progress in finding ways to make the switching function of these memristors behave efficiently. For example, tantalum oxide (TaOₓ)-based memristors have been demonstrated to have superior endurance over other nano-scale devices capable of electronic switching. In lab settings, tantalum oxide-based memristors are capable of over 10 billion switching cycles whereas other memristors, such as tantalum oxide (WOₓ)- or titanium oxide (TiOₓ)-based memristors, may require a sophisticated feedback mechanism for avoiding over-driving the devices or an additional step of refreshing the devices with stronger voltage pulses in order to obtain an endurance in the range of 10 million switching cycles.

Memristor devices typically may comprise two electrodes sandwiching an insulating layer. Conducting channels in the insulating layer between the two electrodes may be formed that are capable of being switched between two states, one in which the conducting channel forms a conductive path between the two electrodes (“ON”) and one in which the conducting channel does not form a conductive path between the two electrodes (“OFF”).

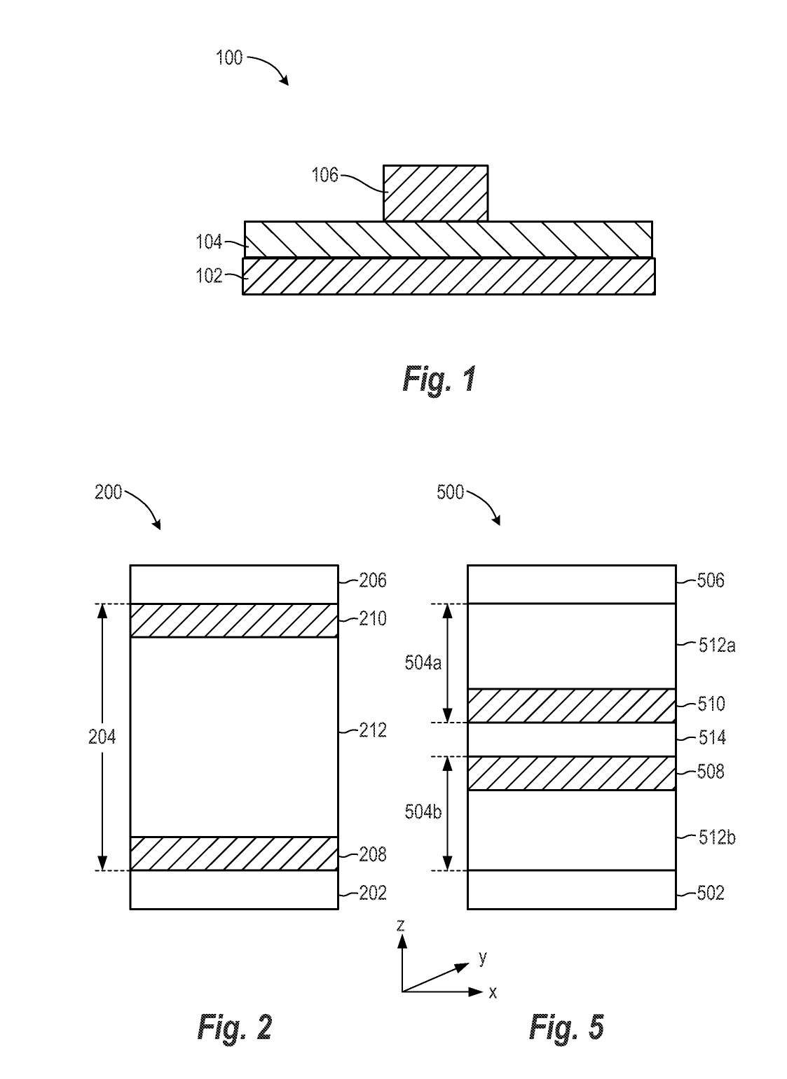

An example of a present device is depicted in FIG. 1. The device 100 comprises a bottom, or first, electrode 102, a metal oxide layer 104, and a top, or second, electrode 106.

In an example, the bottom electrode 102 may be platinum having a thickness of 100 nm, the metal oxide layer 104 may be a metal oxide such as TaOₓ having a thickness of 12 nm, and the top electrode 106 may be tantalum having a thickness of 100 nm.

In some examples, the switching function of the memristor 100 is achieved in the switching layer 104. In general, the switching layer 104 is a weak ionic conductor that is semiconducting and/or insulating without dopants. These materials can be doped with native dopants, such as oxygen vacancies or impurity dopants (e.g., intentionally introducing different metal ions into the switching layer 104). The resulting doped materials are electrically conductive because the dopants are electrically charged and mobile under electric fields. Accordingly, the concentration profile of the dopants inside the switching layer 104 can be reconfigured by electric fields, leading to the resistance change of the device under electric fields, namely, electrical switching.

In some examples, the switching layer 104 may include a transition metal oxide, such as tantalum oxide, titanium oxide, yttrium oxide, hafnium oxide, zirconium oxide, or other like oxides, or may include a metal oxide, such as aluminum oxide, calcium oxide, magnesium oxide, or other like oxides. In one example, the switching layer 104 may include the oxide form of the metal of one of the electrodes 102, 106. In alternate examples, the switching layer 104 may comprise ternary oxides, quaternary oxides, or other complex oxides, such as strontium titanate (STO) or praseodymium calcium manganese oxide (PCMO).

An annealing process or other thermal forming process, such as heating by exposure to a high temperature environment or by exposure to electrical resistance heating or other suitable processes, may be employed to form one or more switching channels (not shown) in the switching layer 104 to cause localized atomic modification in the switching layer. In some examples, the conductivity of the switching channels may be adjusted by applying different biases across the first electrode 102 and the second electrode 106. In other examples, the switching layer 104 may be singularly configurable. In yet other examples, the memristor's switching layer 104 may consist of a relatively thin insulating oxide layer (approximately 5 nm thick) and a relatively thick heavily reduced oxide layer. In these examples, also known as forming-free memristors, no process for forming the switching channels is needed, since the oxide layer is so thin that there is no need to apply a high voltage or heat to form the switching channels. The voltage applied during the operation of the switch is sufficient for forming a switching channel.

In one example, the memristor may be turned OFF and ON when oxygen or metal atoms move in the electric field, resulting in the reconfiguration of the switching channel in the switching layer 104. Particularly, when the atoms move such that the formed switching channel reaches from the first electrode 102 to the second electrode 106, the memristor is in the ON state and has a relatively low resistance to the voltage supplied between the first electrode and the second electrode. Likewise, when the atoms move such that the formed switching channel has a gap known as the switching region (not shown) between the first electrode 102 and the second electrode 106, the memristor is in the OFF state and has a relatively high resistance to the voltage supplied between the first electrode and the second electrode. In some examples, more than one switching channel may be formed in the switching layer 104 upon heating. The switching layer 104 may be between the first electrode 102 and the second electrode 106. In some examples, the first electrode 102 and the second electrode 106 may include any conventional electrode material. Examples of conventional electrode materials may include, but are not limited to, aluminum (Al), copper (Cu), gold (Au), molybdenum (Mo), niobium (Nb), palladium (Pd), platinum (Pt), ruthenium (Ru), ruthenium oxide (RuO₂), silver (Ag), tantalum (Ta), tantalum nitride (TaN), titanium nitride (TiN), tungsten (W), and tungsten nitride (WN).

Metallic nitrides, such as TiN, may be used as the electrode materials for memristor devices. Oxide switching materials with nitride electrodes may not be stable because of chemical reduction of the oxide by off-stoichiometric nitrides. On the other hand, nitride memristive switching materials employing metal electrodes cannot enable billions of switching cycles without a large nitrogen reservoir.

However, some insulating nitrides, such as AlN, can be in thermodynamic equilibrium with a nitride electrode, such as TiN. TiN has a large N solubility, which makes it a candidate memristive electrode material. AlN has a large bandgap and only two solid phases in the Al—N system, both of which make AlN a candidate memristive switching material.

In accordance with the teachings herein, a fully nitride memristor is disclosed. In an example, the nitride-based memristor may comprise a stack of TiN/AlN/TiN. A high endurance, large ON/OFF ratio, low cost, and CMOS compatibility are expected.

FIG. 2 is a view similar to that of FIG. 1, but with the switching layer 104 of FIG. 1 replaced by an active region 204 in FIG. 2. The active region 204 has the same attributes and functionality as the switching layer 104, but may comprise a metal nitride, such as AlN, as described above. Further, the electrodes 202 and 206 have the same attributes and functionality as the electrodes 102, 106, but may comprise a metal nitride, such as TiN, as described above.

FIG. 2 further shows more details for the example memristive element, or memristor, 200 than FIG. 1. The memristive element 200 may include the active region 204 disposed between the first electrode 202 and the second electrode 206. The active region 204 may include one or two switching phases, shown here as layers 208, 210, and a conductive layer 212, formed of a dopant source material. The switching layers 208, 210 may each be formed of a switching material capable of carrying a species of dopants and transporting the dopants under an applied potential. The conductive layer 212 may be disposed between and in electrical contact with the switching layers 208, 210. Conductive layer 212 may be formed of a dopant source material that includes the species of dopants that are capable of drifting into the switching layers under the applied potential and thus changing the conductance of memristive element 200. In some examples, only switching layer 208 may be present; in other examples, only switching layer 210 may be present, and in still other examples, both switching layers 208 and 210 may be present, all depending on the specific requirements on the current-voltage characteristics of the devices 200. In some cases, nitride layers of 202 and 206 may serve as the dopant source materials and the conductive layer 212 may not comprise a dopant source material.

When a potential is applied to memristive element 200 in a first direction (such as in the positive z-axis direction), one of the switching layers (a first switching layer) develops an excess of the dopants and the other switching layer (a second switching layer) develops a deficiency of the dopants. When the direction of the potential is reversed, the voltage potential polarity is reversed, and the drift direction of the dopants is reversed. The first switching layer develops a deficiency of dopants and the second switching layer develops an excess of dopants.

In the device depicted in FIG. 2, at least portions of the active region 204 may be made electrically conductive by introducing nitrogen vacancies therein. The dopant species, namely, nitrogen vacancies V_{N}, diffuses under an electric field (that may be assisted by Joule heating). In those portions, the metal nitride is in a nitrogen-deficient state, represented (in the case of AlN) as AlN₁₋ₓ, where x denotes the nitrogen deficiency from AlN. In some examples, the value of x may be less than 0.2. In other examples, the value of x may be less than 0.02.

Other materials may be used in place of AlN as the active region 204. Examples of such materials include, but are not limited to, nitrides of trivalent elements, such as BN, GaN, and InN, as well as nitrides of metals that have a maximum valence of three and form semiconducting nitrides, such as ScN, YN, LaN, NdN, SmN, EuN, GdN, DyN, HoN, ErN, TmN, YbN, and LuN. Other semi-conducting compounds arise when the total valence of the element complements that of nitrogen for form-filled valence shells, for example, with Si₃N₄ and Ge₃N₄. The electrically conductive portion 212 of such active region 204 may comprise AN₁₋ₓ, where A may be B, Ga, In, Sc, Y, La, Nd, Sm, Eu, Gd, Dy Ho, Er, Tm, Yb, or Lu and the value of x may be less than 0.2, or Si₃N₄₋ₓ or Ge₃N₄₋ₓ, where now the value of x may be less than 0.8. In addition, superior memristor performance may be obtained by using alloys of the above-mentioned compounds with each other or with other nitrides not explicitly mentioned, in any combination. Further, new properties and superior performance can be obtained by using heterostructures composed of multiple layers of different nitrides and/or alloys.

Other materials may be used in place of TiN as the electrodes 202, 206. Examples of such materials include, but are not limited to, the metallic mononitride compounds of non-trivalent transition metals, such as tantalum nitride (TaN), hafnium nitride (HfN), zirconium nitride (ZrN), chromium nitride (CrN), and niobium nitride (NbN), as well as metallic or semimetallic nitrides such as tungsten nitride (WN₂), molybdenum nitride (Mo₂N), and iron nitrides (Fe₂N, Fe₃N, Fe₄N, and Fe₁₆N₂), as well as alloys thereof, such as ternary nitrides.

Further, alloys of these nitrides with other metal nitrides (e.g., AlN) may also be employed to form ternary alloys such as TiAlN. The electrodes 202, 206 may each be composed of the same material or different materials.

Conditions for improved device performance have been identified. These conditions may include (1) thermal stability between the matrix and channels; (2) thermal stability between the electrode(s) and the switching material; and (3) a reservoir for mobile species (N vacancies).

FIG. 3 depicts a ternary phase diagram 300 of the Al—Ti—N system. Associated with the Al—N portion of the ternary phase diagram is a binary phase diagram 302 of the Al—N system, and associated with the Ti—N portion of the ternary phase diagram is a binary phase diagram 304 of the Ti—N system.

An example of thermal stability between the matrix and the channels is provided by Al—N. The Al—N system provides a fairly simple phase diagram 302, in which a single compound, AlN, is formed. Thus, (Al) is in equilibrium with AlN on the Al side, and N is in equilibrium with AlN on the N side. (Al) refers to Al metal with a certain amount of N solute.

An example of thermal stability between the electrode(s) and the switching material is provided by TiN—AlN, shown in the Al—Ti—N ternary phase diagram 300. A tie-line 306 connects the AlN and TiN phases in the ternary phase diagram 300, indicating these two phases are in thermodynamically equilibrium, that is, there is no reaction between these two phases even at a high temperature induced by electrical heating in switching operations. Based on this, the complete structure (electrode/active layer/electrode) of the memristor may be provided by the combination TiN/AlN/TiN.

An example of a reservoir for mobile species, here, N vacancies, is a material that has a large solubility for the mobile species, namely, TiN, such as shown in the Ti—N binary phase diagram 304.

Thus, a fully nitride memristor may include, as one example, TiN (electrode 202)/AlN (active region 204) with electrically conductive portion(s) AlN₁₋ₓ (212)/TiN (electrode 206), or, more simply, TiN/AlN—AlN₁₋ₓ/TiN. The TiN has a large solubility for N, making it a suitable electrode serving as a reservoir and sink of N vacancies. AlN has only two stable solid phases (like Ta—O, another material commonly used in memristors). AlN is a large bandgap insulator, leading to a large ON/OFF conductance ratio, as well as decreasing leakage current and therefore parasitic resistance. The TiN/AlN—AlN₁₋ₓ /TiN system is thermally stable and no thermal reaction occurs due to electrical heating, which may adversely change the device states. Finally, based on the foregoing items, this system may have great endurance, on the order of at least billions of switching cycles.

Likewise, in another example, a fully nitride memristor may comprise TiN (electrode 202)/Si₃N₄ (active region 204) with electrically conductive portion(s) Si₃N₄₋ₓ (212)/TiN (electrode 206), or, more simply, TiN/Si₃N₄—Si₃N₄₋ₓ/TiN.

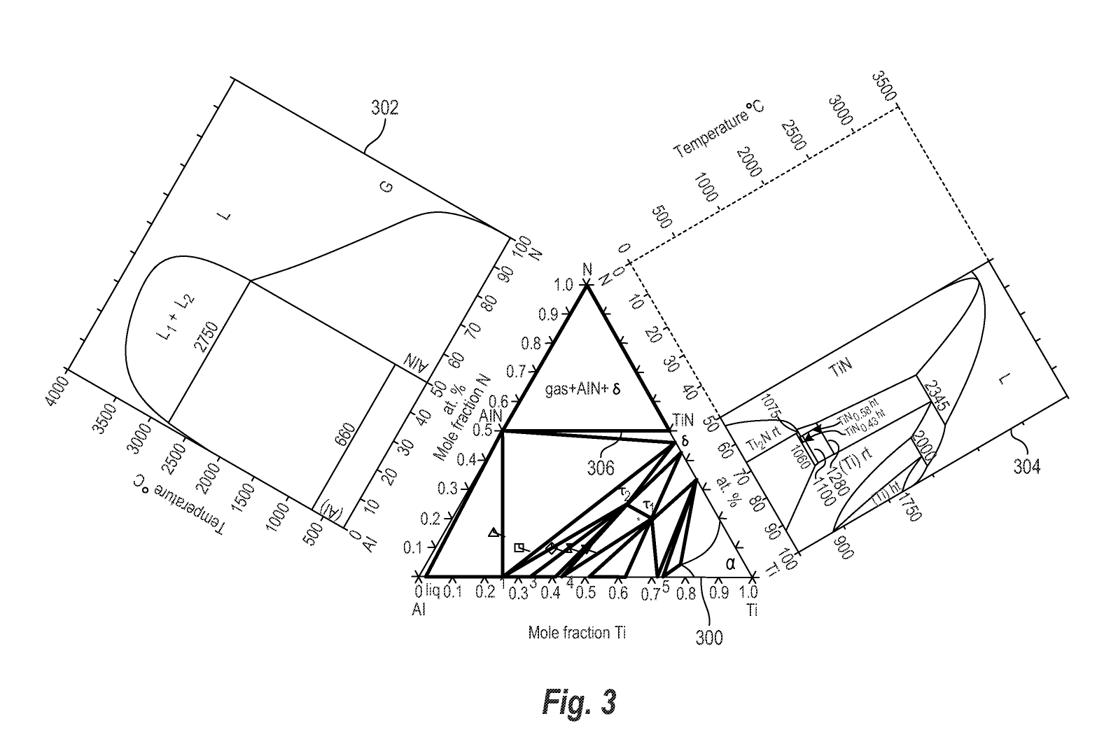

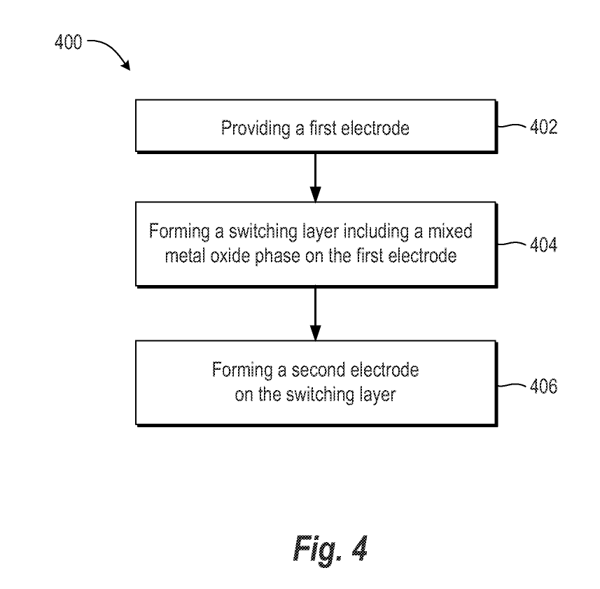

FIG. 4 is a flow chart depicting an example method 400 for fabricating a memristor in accordance with the examples disclosed herein. It should be understood that the method 400 depicted in FIG. 4 may include additional steps and that some of the steps described herein may be removed and/or modified without departing from the scope of the method 400.

First, the bottom, or first, electrode 202 may be formed 402, such as by sputtering, evaporation, ALD, co-deposition, chemical vapor deposition, IBAD (ion beam assisted deposition), or any other film deposition technology. The thickness of the first electrode 202 may be in the range of about 50 nm to a few micrometers.

The active region 204 may then be formed 404 on the electrode 202. In one example, the active region 204 is an electronically semiconducting or nominally insulating and weak ionic conductor. The active region 204 may be deposited by sputtering, atomic layer deposition, chemical vapor deposition, evaporation, co-sputtering (using two metal oxide targets, for example), or other such process. The thickness of the active region 204 may be approximately 4 to 50 nm.

The top, or second, electrode 206 may be formed 406 on the active region 204. The electrode 306 may be provided through any suitable formation process, such as described above for forming the first electrode 302. In some examples, more than one electrode may be provided. The thickness of the second electrode 306 may be in the range of about 50 nm to a few micrometers.

In some examples, a switching channel (not shown) may be formed. In an example, the switching channel is formed by heating the active region 204. Heating can be accomplished using many different processes, including thermal annealing or running an electrical current through the memristor. In other examples, wherein a forming-free memristor with built-in conductance channels is used, no heating may be required as the switching channels are built in and as discussed previously, the application of the first voltage, which may be approximately the same as the operating voltage, to the virgin state of the memristor 200 may be sufficient for forming a switching channel.

The sequence of the formation of the bottom and top electrodes 202, 206 may be changed in some cases.

FIG. 5 shows another example memristive element 500 according to principles described herein. The memristive element 500 includes two active regions 504a, 504b disposed between a first electrode 502 and a second electrode 506. Each of the active regions 504a, 504b may include a switching layer 508, 510 formed of a switching material capable of carrying a species of dopants and a conductive layer 512a, 512b formed of a dopant source material. A third, or middle, electrode 514 is disposed between and in electrical contact with both of the active regions 504a, 504b.The relative position of elements 510 and 512a can be swapped and the relative position of elements 508 and 512b can also be swapped.

When a potential is applied to memristive element 500 in a first direction (such as in the positive z-axis direction), one of the switching layers (a first switching layer) develops an excess of the dopants and the other switching layer (a second switching layer) develops a deficiency of the dopants. When the direction of the potential is reversed the voltage potential polarity is reversed, and the drift direction of the dopants is reversed. The first switching layer develops a deficiency of dopants and the second switching layer develops an excess of dopants. The third electrode 514 can block the mobile dopant species and also tune the contact property of this interface depending on relative the work functions of the electrode and the memristive nitrides.

It should be understood that the memristors 200, 500 described herein, such as the example memristors depicted in FIGS. 2 and 5, may include additional components and that some of the components described herein may be removed and/or modified without departing from the scope of the memristor disclosed herein. It should also be understood that the components depicted in the Figures are not drawn to scale and thus, the components may have different relative sizes with respect to each other than as shown therein. For example, the upper, or second, electrode 206 may be arranged substantially perpendicularly to the lower, or first, electrode 202 or may be arranged at some other non-zero angle with respect to each other. As another example, the active region 204 may be relatively smaller or relatively larger than either or both electrode 202 and 206.

The fully nitride memristor 200 may solve reliability and stability issues of oxide-based memristors with nitride electrodes due to reactions between the oxide switching layer 104 and the nitride electrodes 102, 106. Replacing the oxide switching layer 104 with a nitride active region 204 may reduce such reactions.

The fully nitride memristor may have high endurance, a simple structure, long term reliability, and low cost.

1. A nitride-based memristor including:
a first electrode comprising a first nitride material;
a second electrode comprising a second nitride material; and
an active region positioned between the first electrode and the second electrode, wherein the active region includes an electrically semiconducting or nominally insulating and weak ionic switching nitride phase.

2. The memristor of claim 1 further including a third electrode comprising a third nitride material, disposed in the active region so as to form two separate active regions.

3. The memristor of claim 1, wherein each electrode comprises a nitride independently selected from the group consisting of:
metallic mononitride compounds of non-trivalent transition metals;
metallic nitrides; and
semimetallic nitrides.

4. The memristor of claim 3 wherein each electrode comprises a nitride independently selected from the group consisting of:
tantalum nitride, hafnium nitride, zirconium nitride, chromium nitride, and niobium nitride;
titanium nitride, tungsten nitride, molybdenum nitride, and iron nitrides; and
alloys thereof, and alloys with other metal nitrides.

5. The memristor of claim 1, wherein the active region is selected from the group consisting of:
nitrides of trivalent elements;
nitrides of metals that have a maximum valence of three and form semiconducting nitrides; and
elements that complement that of nitrogen for form-filled valence shells.

6. The memristor of claim 5, wherein the active region is selected from the group consisting of:
AlN, BN, GaN, and InN;
ScN, YN, LaN, NdN, SmN, EuN, GdN, DyN, HoN, ErN, TmN, YbN, and LuN; and
Si₃N₄ and Ge₃N₄.

7. The memristor of claim 5, wherein the switching nitride phase is selected from the group consisting of:
AN₁₋ₓ, where A is selected from the group consisting of Al, B, Ga, In, Sc, Y, La, Nd, Sm, Eu, Gd, Ho, Er, Tm, Yb, and Lu and where x is less than 0.2; and
Si₃N₄₋ₓ and Ge₃N₄₋ₓ, where x is less than 0.8; and
alloys thereof, and alloys with other nitrides.

8. The memristor of claim 1, wherein the first electrode comprises titanium nitride, the active region comprises aluminum nitride, the switching nitride phase comprise AlN₁₋ₓ, where x is less than 0.2, and the second electrode comprises titanium nitride.

9. The memristor of claim 1, wherein the first electrode comprises titanium nitride, the active region comprises silicon nitride, the switching nitride phase comprises Si₃N₄₋ₓ, where x is less than 0.8, and the second electrode comprises titanium nitride.

10. The memristor of claim 1, wherein each active region or a part thereof is to form a switching channel.

11. The memristor of claim 1, wherein each electrode has a thickness of 50 nm or greater and wherein each active region has a thickness in the range of 4 to 50 nm.

12. The memristor of claim 1, wherein the active region comprises a heterostructure comprising multiple layers of different nitrides.

13. A method for fabricating a nitride-based memristor including:
a first electrode comprising a first nitride material;
a second electrode comprising a second nitride material; and
an active region positioned between the first electrode and the second electrode, wherein the active region includes an electrically semiconducting or nominally insulating and weak ionic switching nitride phase,
the method including:
providing the first electrode;
forming the active region on the first electrode; and
forming the second electrode on the active region.

14. The method of claim 13 further including forming a switching channel in the active region.

15. A method for fabricating a nitride-based memristor including:
a first electrode comprising a first nitride material;
a second electrode comprising a second nitride material;
an active region positioned between the first electrode and the second electrode, wherein the active region includes an electrically semiconducting or nominally insulating and weak ionic switching nitride phase; and
a third electrode comprising a third nitride material, disposed in the active region so as to form two separate active regions
the method including:
providing the first electrode;
forming the first active region on the first electrode;
forming the third electrode on the first active region;
forming the second active region on the third electrode; and
forming the second electrode on the second active region.
